(19) United States
(12) Patent Application Publication
(10) Pub. No.: US 2025/0167739 A1
(43) Pub. Date: May 22, 2025

(54) LOW NOISE AMPLIFIER AND SENSOR DEVICE

(71) Applicant: Sony Semiconductor Solutions Corporation, Kanagawa (JP)

(72) Inventor: Kazutoshi Ono, Fukuoka (JP)

(21) Appl. No.: 18/832,331

(22) PCT Filed: Jan. 13, 2023
(86) PCT No.: PCT/JP2023/000766

§ 371 Date: Jan. 23, 2025

(30) Foreign Application Priority Data
Mar. 11, 2022 (JP) 2022-037680

(51) Int. Cl. H03F 3/21; G01N 22/04

(52) U.S. Cl. CPC H03F 3/21; G01N 22/04; H03F 2200/294

(57) ABSTRACT

In a low noise amplifier in which a common-source amplifier circuit is used, frequency characteristics are improved while noise is reduced.

The low noise amplifier includes a common-gate amplifier circuit, an inverting amplifier circuit, and a negative feedback resistor. In the low noise amplifier, the common-gate amplifier circuit amplifies a reception signal and outputs the amplified reception signal as an internal signal. In addition, in the low noise amplifier, the inverting amplifier circuit inverts and amplifies the internal signal and outputs the inverted and amplified internal signal as an output signal. Moreover, the negative feedback resistor is inserted between an input terminal and an output terminal of the inverting amplifier circuit.

### TECHNICAL FIELD

The present technology relates to a low noise amplifier. Specifically, the present technology relates to a low noise amplifier that amplifies a signal from an antenna, and a sensor device.

### BACKGROUND ART

Conventionally, a low noise amplifier (LNA) has been used to amplify a signal from an antenna in a wireless communication device or the like. For example, there has been proposed an LNA in which a common-gate amplifier circuit including transistors M1 and M2 having a source connected to an input terminal and a drain connected to an output terminal and a load resistor connected to the drains are disposed (see, for example, Patent Document 1). Furthermore, in the LNA, a common-source amplifier circuit including transistors M3 and M4 is connected to the outputs of the transistors M1 and M2.

### CITATION LIST

### Patent Document

Patent Document 1: Japanese Patent Application Laid-Open No. 2015-122678

### SUMMARY OF THE INVENTION

### Problems to be Solved by the Invention

The above-described conventional technique achieves high gain and low noise by connecting the common-source amplifier circuit including the transistors M3 and M4 to the output of the common-gate amplifier circuit including the transistors M1 and M2. However, in the above-described LNA, there are many elements to be connected as seen from the input side, and there is a concern that the parasitic capacitance will increase. In particular, the value of the parasitic capacitance between the gate and the drain of the transistors M3 and M4 and the like may increase because of a mirror effect. It is therefore hard to achieve a higher frequency. In addition, as the value of load resistance increases, noise generated in the LNA can be reduced, while the gain variation due to a frequency change increases and the frequency characteristics deteriorate. As described above, in the above-described LNA, it is hard to improve the frequency characteristics while reducing noise.

The present technology has been made in view of such a situation, and an object thereof is to improve the frequency characteristics while reducing noise in a low noise amplifier in which a common-gate amplifier circuit is used.

### Solutions to Problems

The present technology has been made to solve the above-described problems, and a first aspect thereof is a low noise amplifier including: a common-gate amplifier circuit that amplifies a reception signal and outputs the amplified reception signal as an internal signal; an inverting amplifier circuit that inverts and amplifies the internal signal and outputs the inverted and amplified internal signal as an output signal; and a negative feedback resistor inserted between an input terminal and an output terminal of the inverting amplifier circuit. This brings about the effect of improving the noise characteristics and the frequency characteristics.

In addition, in the first aspect, the common-gate amplifier circuit may include: an amplifier transistor that amplifies the reception signal input to the source and outputs the amplified reception signal from the drain; and a load resistor inserted between the drain of the amplifier transistor and a node of a predetermined voltage. This brings about the effect of connecting the load resistor and the inverting amplifier circuit with the negative feedback resistor in parallel.

Moreover, in the first aspect, the inverting amplifier circuit may include: an inverting amplifier transistor that inverts and amplifies the internal signal input to the gate and outputs the inverted and amplified internal signal from the drain; and an active inductor connected to the drain of the inverting amplifier transistor. This brings about the effect of being able to achieve a higher band.

Furthermore, in the first aspect, the reception signal and the internal signal may be single-ended signals. This brings about the effect of reducing a circuit scale and power consumption as compared to those in a case where a differential signal is amplified.

In addition, in the first aspect, the reception signal and the internal signal may be differential signals, and the common-gate amplifier circuit and the inverting amplifier circuit may be circuits that perform differential amplification. This brings about the effect of further reducing noise.

Moreover, a second aspect of the present technology is a sensor device including: a common-gate amplifier circuit that amplifies a reception signal and outputs the amplified reception signal as an internal signal; an inverting amplifier circuit that inverts and amplifies the internal signal and outputs the inverted and amplified internal signal as an output signal; a negative feedback resistor inserted between an input terminal and an output terminal of the inverting amplifier circuit; and a mixer that mixes the output signal and a predetermined local signal. This brings about the effect of improving the noise characteristics and the frequency characteristics on the reception side in the sensor device.

Furthermore, in the second aspect, a transmitter that outputs a transmission signal may be further included. The common-gate amplifier circuit, the inverting amplifier circuit, the negative feedback resistor, and the mixer may be disposed in a receiver, and the transmitter and the receiver may be disposed on a predetermined semiconductor chip. This brings about the effect of improving the noise characteristics and the frequency characteristics of the receiver that is required to be isolated from the transmitter.

In addition, in the second aspect, a directional coupler that separates an incident wave and a reflected wave in the transmission signal may be further included. The receiver may include: an incident wave receiver that receives the incident wave; a reflected wave receiver that receives the reflected wave; and a transmitted wave receiver that receives a transmitted wave transmitted through a predetermined medium. The common-gate amplifier circuit, the inverting amplifier circuit, the negative feedback resistor, and the mixer may be disposed in the transmitted wave receiver. This brings about the effect of improving the noise characteristics and the frequency characteristics of the transmitted wave receiver.

Moreover, in the second aspect, the frequency of the local signal may be 1 to 9 gigahertz (GHz). This brings about the effect of using the sensor device for measuring the amount of moisture.

Furthermore, in the second aspect, a coefficient calculation unit that calculates a coefficient for measuring the amount of moisture in the medium on the basis of the output signal may be further included. This brings about the effect of using the sensor device for measuring the amount of moisture.

### BRIEF DESCRIPTION OF DRAWINGS

FIG. 1 is an overall view illustrating a configuration example of a moisture measurement system in a first embodiment of the present technology.

FIG. 2 is a block diagram illustrating a configuration example of a sensor device in the first embodiment of the present technology.

FIG. 3 is a circuit diagram illustrating configuration examples of a transmitter, an incident wave receiver, a reflected wave receiver, and a transmitted wave receiver in the first embodiment of the present technology.

FIG. 4 is a circuit diagram illustrating a configuration example of a low noise amplifier in the first embodiment of the present technology.

FIG. 5 is a circuit diagram illustrating a configuration example of the low noise amplifier in a comparative example.

FIG. 6 is a graph illustrating examples of the noise characteristics and the frequency characteristics of the low noise amplifier in the comparative example.

FIG. 7 is a diagram illustrating examples of the noise characteristics and the frequency characteristics of the low noise amplifier in the first embodiment and the comparative example of the present technology.

FIG. 8 is a circuit diagram illustrating a configuration example of a negative feedback amplifier circuit in the first embodiment of the present technology.

FIG. 9 is a circuit diagram illustrating a configuration example of an active inductor in the first embodiment of the present technology.

FIG. 10 is a graph illustrating an example of the frequency characteristics of the active inductor in the first embodiment of the present technology.

FIG. 11 is a diagram illustrating examples of circuits used in simulations in the first embodiment of the present technology.

FIG. 12 is a graph illustrating an example of simulation results in the first embodiment of the present technology.

FIG. 13 is a block diagram illustrating a configuration example of a sensor control unit in the first embodiment of the present technology.

FIG. 14 is a block diagram illustrating a configuration example of a central processing unit in the first embodiment of the present technology.

FIG. 15 is a circuit diagram illustrating a configuration example of a common-gate amplifier circuit in a second embodiment of the present technology.

FIG. 16 is a circuit diagram illustrating a configuration example of a negative feedback amplifier circuit in the second embodiment of the present technology.

FIG. 17 is a circuit diagram illustrating a configuration example of an active inductor in the second embodiment of the present technology.

### MODE FOR CARRYING OUT THE INVENTION

Modes for carrying out the present technology (hereinafter, referred to as embodiments) will be described hereinafter. The description will be given in the following order.
1. First Embodiment (example in which a negative feedback amplifier circuit is connected to a common-gate amplifier circuit)
2. Second Embodiment (example in which a negative feedback amplifier circuit is connected to a common-gate amplifier circuit that amplifies differential signals)

### 1. First Embodiment

### Configuration Example of Moisture Measurement System

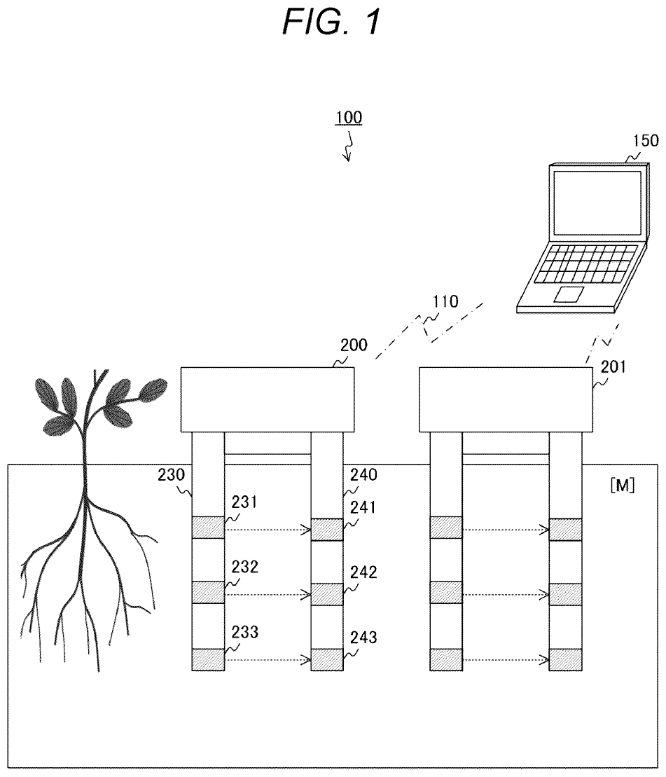

FIG. 1 is an example of an overall view of a moisture measurement system 100 in a first embodiment of the present technology. The moisture measurement system 100 measures the amount of moisture contained in a medium M, and includes a central processing unit 150 and a predetermined number of sensor devices such as sensor devices 200 and 201. As the medium M, soil for growing crops is assumed, for example.

The sensor device 200 acquires data necessary to measure the amount of moisture as measurement data. The content of the measurement data will be described later. The sensor device 200 transmits the measurement data to the central processing unit 150 via a communication path 110 (such as a wireless communication path). The configuration of the sensor device 201 is similar to that of the sensor device 200. The central processing unit 150 measures the amount of moisture, using the measurement data. Note that the communication path 110 may be a path of wired communication.

A user uses the sensor devices 200 and 201 by applying a load to them from above the soil and inserting them into the soil. The sensor device 200 and the like are used with their antenna parts for communicating with the central processing unit 150 exposed above the soil surface. Note that the above-described antenna parts may be buried in the soil as long as they are buried at a depth that allows communication with the central processing unit 150.

Each of the sensor devices 200 and 201 includes a transmission probe 230 and a reception probe 240. The length of these probes is 5 to 200 centimeters (cm), and each of the probes is provided with 1 to 40 antennas for measuring moisture.

For example, the transmission probe 230 is provided with transmission antennas 231 to 233, and the reception probe 240 is provided with reception antennas 241 to 243. These antennas are arranged in the depth direction. An electromagnetic wave is transmitted from the transmission antenna 231 or the like to the reception antenna 241 or the like, and the amount of moisture is measured from its propagation delay time. This enables the amount of moisture to be measured, for example, at a plurality of depths within a range of 5 to 200 centimeters (cm) in depth in the soil.

### Configuration Example of Sensor Devices

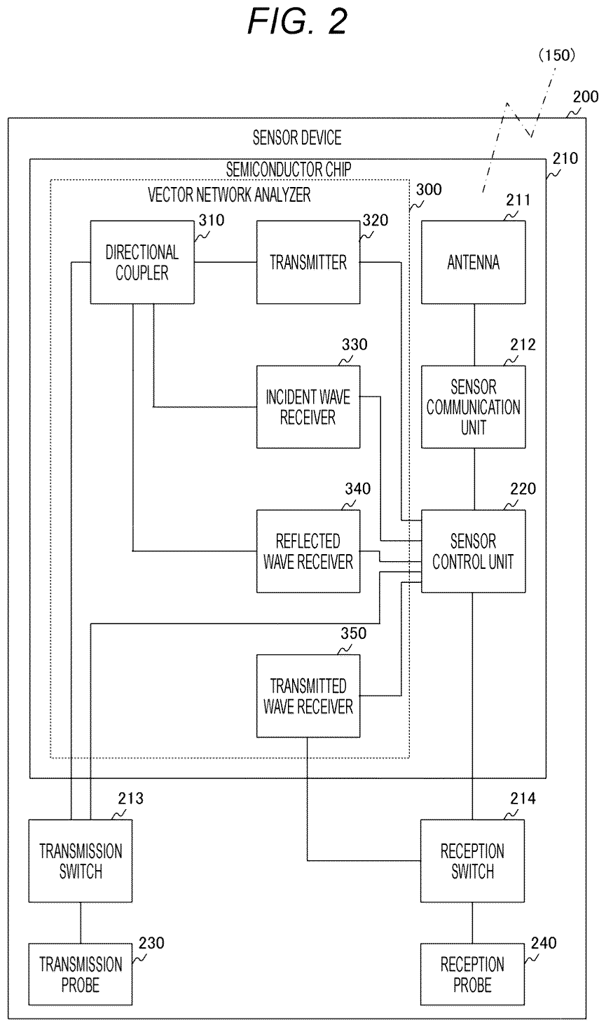

FIG. 2 is a block diagram illustrating a configuration example of the sensor device 200 in the first embodiment of the present technology. The sensor device 200 includes a semiconductor chip 210, a transmission switch 213, a reception switch 214, the transmission probe 230, and the reception probe 240. On the semiconductor chip 210, a vector network analyzer 300, an antenna 211, a sensor communication unit 212, and a sensor control unit 220 are disposed.

The sensor control unit 220 controls each circuit in the semiconductor chip 210. The transmission switch 213 selects one of a predetermined number of transmission antennas (not illustrated) such as the transmission antennas 231 to 233 under the control of the sensor control unit 220, and is connected to a directional coupler 310. The reception switch 214 selects one of reception antennas (not illustrated) such as the reception antennas 241 to 243 under the control of the sensor control unit 220, and is connected to a transmitted wave receiver 350.

The vector network analyzer 300 measures a scattering (S) parameter. The vector network analyzer 300 includes the directional coupler 310, a transmitter 320, an incident wave receiver 330, a reflected wave receiver 340, and the transmitted wave receiver 350.

The transmitter 320 transmits an electric signal of a predetermined frequency as a transmission signal via the selected transmission antenna. As an incident wave in the transmission signal, for example, a continuous wave (CW) is used. The transmitter 320, for example, transmits a transmission signal, sequentially switching the frequency in steps of 50 megahertz (MHz) within a frequency band of 1 to 9 gigahertz (GHz).

The directional coupler 310 supplies a transmission signal to the transmission switch 213 and separates the transmission signal into an incident wave and a reflected wave. Here, the reflected wave is an incident wave reflected at the terminal of the transmission probe 230. The directional coupler 310 supplies the incident wave to the incident wave receiver 330 and supplies the reflected wave to the reflected wave receiver 340.

The incident wave receiver 330 receives the incident wave separated by the directional coupler 310. The incident wave receiver 330 measures an S parameter indicating the received incident wave, and supplies the S parameter to the sensor control unit 220.

The reflected wave receiver 340 receives the reflected wave separated by the directional coupler 310. The reflected wave receiver 340 measures an S parameter indicating the received reflected wave and supplies the S parameter to the sensor control unit 220.

The transmitted wave receiver 350 receives a transmitted wave from the reception switch 214. Here, the transmitted wave is an electromagnetic wave transmitted through a medium such as soil. The transmitted wave receiver 350 measures an S parameter indicating the received transmitted wave, and supplies the S parameter to the sensor control unit 220.

The sensor control unit 220 calculates a reflection coefficient and a transmission coefficient from the S parameters measured by the incident wave receiver 330, the reflected wave receiver 340, and the transmitted wave receiver 350, respectively. A method of calculating the coefficients will be described later. Then, the sensor control unit 220 supplies data indicating the coefficients to the sensor communication unit 212 as measurement data.

The sensor communication unit 212 receives information (instruction on measurement and the like) transmitted from the central processing unit 150, and transmits measurement data to the central processing unit 150 via the antenna 211.

Note that the configuration of the sensor device 201 is similar to that of the sensor device 200.

### Configuration Examples of Transmitter and Receivers

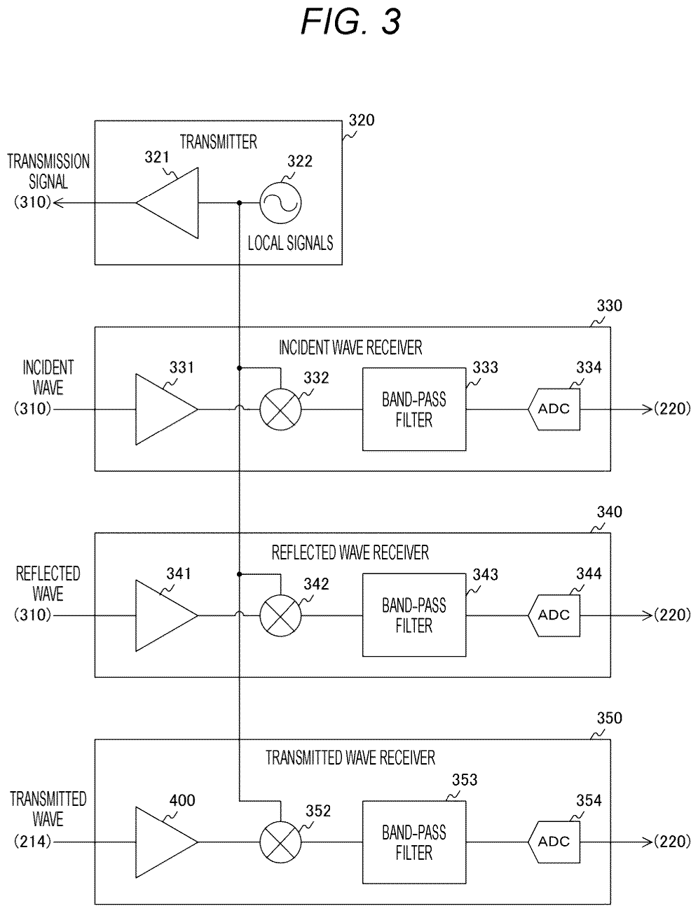

FIG. 3 is a circuit diagram illustrating configuration examples of the transmitter 320, the incident wave receiver 330, the reflected wave receiver 340, and the transmitted wave receiver 350 in the first embodiment of the present technology.

The transmitter 320 includes a power amplifier 321 and a local oscillator 322. The local oscillator 322 generates two local signals different in phase by 90 degrees. The local oscillator 322 supplies the generated local signals to each of the power amplifier 321, the incident wave receiver 330, the reflected wave receiver 340, and the transmitted wave receiver 350. The power amplifier 321 amplifies the local signals and supplies the amplified local signals to the directional coupler 310 as transmission signals.

The incident wave receiver 330 includes a low noise amplifier 331, a mixer 332, a band-pass filter 333, and an analog to digital converter (ADC) 334. The low noise amplifier 331 amplifies an incident wave and supplies the amplified incident wave to the mixer 332.

The mixer 332 performs quadrature detection by mixing two local signals different in phase by 90 degrees with a transmission signal (incident wave). An S parameter including an in-phase component and a quadrature component is obtained by the quadrature detection. The mixer 332 supplies the S parameters to the ADC 334 via the band-pass filter 333.

The band-pass filter 333 passes a component of a predetermined frequency band. The ADC 334 performs analog to digital (AD) conversion on the in-phase component and the quadrature component and supplies them to the sensor control unit 220.

The reflected wave receiver 340 includes a low noise amplifier 341, a mixer 342, a band-pass filter 343, and an ADC 344. The configurations of these circuits are similar to the circuits with the same names in the incident wave receiver 330.

The transmitted wave receiver 350 includes a low noise amplifier 400, a mixer 352, a band-pass filter 353, and an ADC 354. The configurations of these circuits are similar to the circuits with the same names in the incident wave receiver 330. Note that each of the mixers 332, 342, and 352 includes the two mixers of an in-phase side mixer and a quadrature side mixer, but one of them is omitted in the figure for convenience of description.

In applications for measuring the amount of moisture in the soil, the above-described receivers (the incident wave receiver 330, the reflected wave receiver 340, and the transmitted wave receiver 350) are required to satisfy the following three requirements.
(a) First, the receivers must operate in a wide and high band such as a band of 1 to 9 gigahertz (GHz) (in other words, the frequency characteristics must be good).
(b) Second, intrinsic noise generated in the transmitted wave receiver 350 must be low, particularly because the transmitted wave receiver 350 receives a minute signal (in other words, the noise characteristics must be good).
(c) Third, the isolation must be increased, because the transmitter and the receivers are disposed on the same semiconductor chip 210, and particularly because the transmitted wave receiver 350 receives a minute signal. For example, it is necessary to increase resistance to electromagnetic interference (EMI) from the transmitter 320 to the transmitted wave receiver 350.

The degree of the sum of (b) intrinsic noise and (c) extrinsic noise due to electromagnetic interference (EMI) is expressed by, for example, a noise figure (NF).

A circuit configuration of the low noise amplifier 400 in the transmitted wave receiver 350 for satisfying the above-described requirements will be described.

### Configuration Example of Low Noise Amplifier

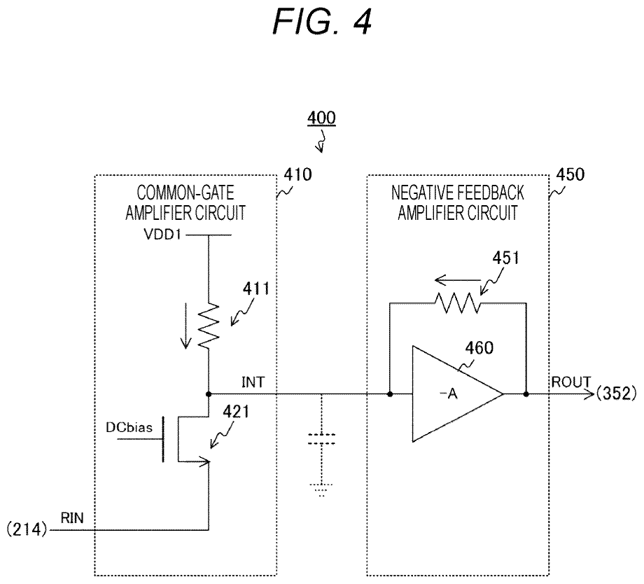

FIG. 4 is a circuit diagram illustrating a configuration example of the low noise amplifier 400 in the first embodiment of the present technology. The low noise amplifier 400 includes a common-gate amplifier circuit 410 and a negative feedback amplifier circuit 450.

The common-gate amplifier circuit 410 includes an amplifier transistor 421 and a load resistor 411. As the amplifier transistor 421, an nMOS transistor is used, for example. A reception signal RIN from the reception switch 214 is input to the source of the amplifier transistor 421. The amplifier transistor 421 amplifies the reception signal RIN and outputs it from the drain as an internal signal INT. Note that a capacitance of dotted lines is a parasitic capacitance of a path for transmitting the internal signal INT. In addition, the reception signal RIN and the internal signal INT are single-ended signals.

The load resistor 411 is inserted between a node of a power supply voltage VDD1 and the drain of the amplifier transistor 421.

The negative feedback amplifier circuit 450 includes an inverting amplifier circuit 460 and a negative feedback resistor 451. The inverting amplifier circuit 460 inverts and amplifies the internal signal INT and outputs it to the mixer 352 as an output signal ROUT.

The negative feedback resistor 451 is inserted between an input terminal and an output terminal of the inverting amplifier circuit 460. An arrow in the figure indicates a direction in which a noise current flows.

Note that an nMOS transistor is used as the amplifier transistor 421, while a pMOS transistor also can be used instead of the nMOS transistor. In this case, the load resistor 411 is inserted between the node and the drain of a ground voltage.

Furthermore, the circuit configuration of the low noise amplifier disposed in each of the incident wave receiver 330 and the reflected wave receiver 340 may be the same as or different from that of the circuit illustrated in the figure.

Here, a configuration not including the negative feedback amplifier circuit 450 and including only the common-gate amplifier circuit 410 is assumed as a comparative example in order to describe an effect brought about by disposing the negative feedback amplifier circuit 450.

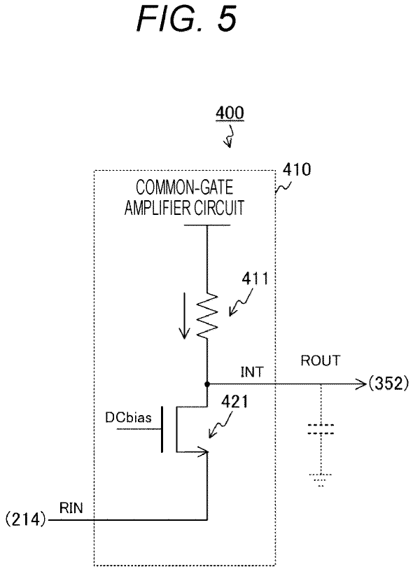

FIG. 5 is a circuit diagram illustrating a configuration example of the low noise amplifier 400 in the comparative example. The common-gate amplifier circuit 410 has a small input capacitance and thus, obviously, it is suitable for achieving a higher band. However, as the value of the load resistor 411 increases, the time constant of the output node increases, so that the frequency characteristics deteriorate but the noise characteristics are excellent. Conversely, as the value of the load resistor 411 decreases, the time constant of the output node decreases, so that the frequency characteristics are good but the noise characteristics deteriorate. That is, in the determination of the resistance value of the load resistor 411, there is a trade-off between the noise characteristics and the frequency characteristics.

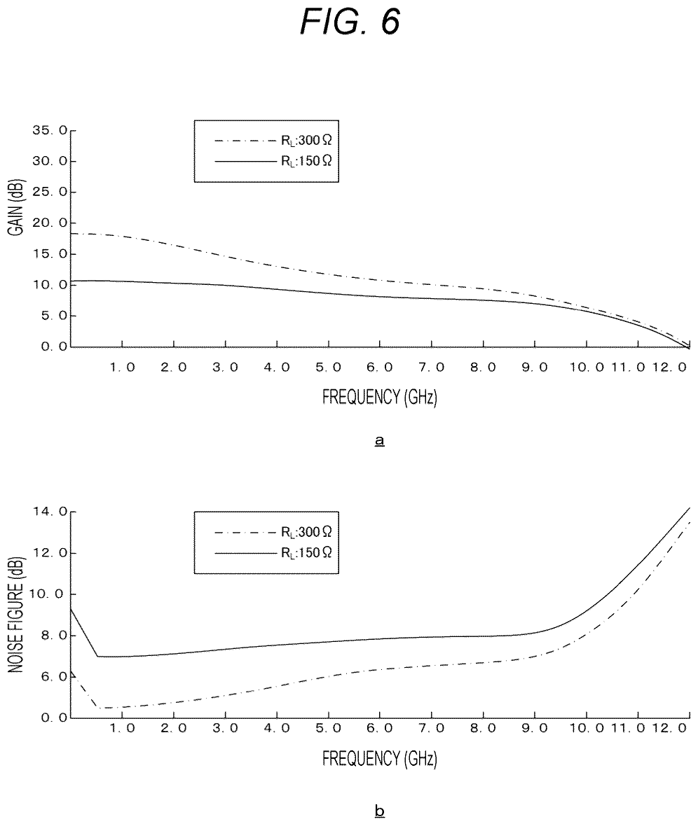

FIG. 6 is a graph illustrating an example of the noise characteristics and the frequency characteristics of the low noise amplifier in the comparative example. In the figure, a is a graph illustrating an example of the noise characteristics of the comparative example, and b is a graph illustrating an example of the frequency characteristics of the comparative example.

In a of the figure, the vertical axis represents the gain of the low noise amplifier, and the horizontal axis represents the frequency. In b of the figure, the vertical axis represents the noise figure, and the horizontal axis represents the frequency. In addition, in a and b of the figure, solid curves indicate the characteristics when the resistance value R_{L} of the load resistor 411 is 150 ohms (Ω), and dash-dotted curves indicate the characteristics when the resistance value R_{L} is 300 ohms (Ω).

As illustrated in a of the figure, the gain variation amount according to the frequency variation is relatively large and the frequency characteristics deteriorate, in a case where the resistance value R_{L} is 300 ohms (Ω) and is relatively large. Conversely, the gain variation amount according to the frequency variation is relatively small and the frequency characteristics are good, in a case where the resistance value R_{L} is 150 ohms (Ω) and is relatively small.

In addition, as illustrated in b of the figure, the noise figure is relatively small and the noise characteristics are good, in a case where the resistance value R_{L} is 300 ohms (Ω) and is relatively large. Conversely, the noise figure is relatively large and the noise characteristics deteriorate, in a case where the resistance value R_{L} is 150 ohms (Ω) and is relatively small.

As illustrated in the figure, in the comparative example, there is a trade-off between the noise characteristics and the frequency characteristics. In order to solve this problem, in the first embodiment, the inverting amplifier circuit 460 with the negative feedback resistor 451 is connected to the drain of the common-gate amplifier circuit 410 as illustrated in FIG. 4.

In the circuit configuration illustrated in FIG. 4, the common-gate amplifier circuit 410 is disposed on the input side, so that one transistor, which is the minimum number of elements, is seen from the input side. This enables a wider and higher band. Furthermore, the capacitance of the output node of the amplifier transistor 421 can be reduced by the connection of the negative feedback amplifier circuit 450. This is described in, for example, Behzad Razavi, “Introduction to RF Microelectronics”, Maruzen Publishing Co., Ltd., p. 360 to p. 362. Reducing the capacitance of the output node enables a higher band. The requirement (a) can be satisfied by achieving a wider and higher band in this way.

In addition, the impedance of the negative feedback amplifier circuit 450 is (Rf/A), where Rf is the resistance value of the negative feedback resistor 451 and—A is the gain of the inverting amplifier circuit 460. Since the negative feedback amplifier circuit 450 and the load resistor 411 are connected in parallel, the combined impedance Z thereof is expressed as the following equation.

$$1 / Z = 1 / {R}_{L} + ( A / Rf ) \qquad Equation 1$$

According to the above equation, an increase in the overall impedance can be suppressed by increasing A and the resistance value Rf, even if the resistance value R_{L} is large. Thus, in a wider band, noise can be made lower than that in the comparative example. Accordingly, the requirements (b) and (c) can be satisfied.

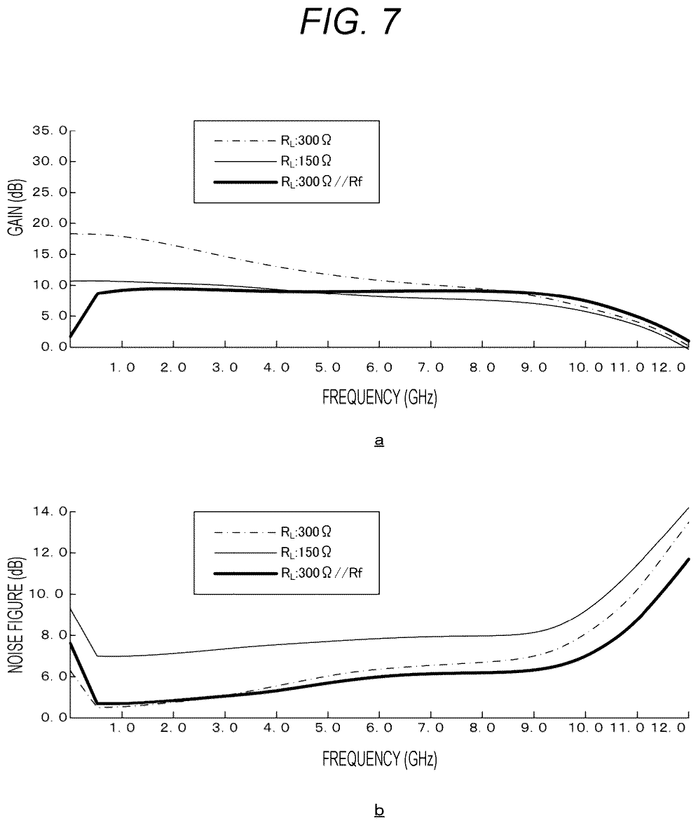

FIG. 7 is a diagram illustrating examples of the noise characteristics and the frequency characteristics of the low noise amplifier 400 in the first embodiment and the comparative example of the present technology. In the figure, a is a graph illustrating examples of the noise characteristics of the first embodiment and the comparative example, and b is a graph illustrating examples of the frequency characteristics of the first embodiment and the comparative example.

In a of the figure, the vertical axis represents the gain of the low noise amplifier, and the horizontal axis represents the frequency. In b of the figure, the vertical axis represents the noise figure, and the horizontal axis represents the frequency. Moreover, in a and b of the figure, thin solid curves indicate the characteristics of the comparative example in a case where the resistance value R_{L} of the load resistor 411 is 150 ohms (Ω), and dash-dotted curves indicate the characteristics of the comparative example in a case where the resistance value R_{L} is 300 ohms (Ω). Thick solid curve indicates the characteristics of the first embodiment in a case where the resistance value R_{L} is 300 ohms (Ω) and Rf/A is 1.5 kilohms (kΩ).

As illustrated in a of the figure, the frequency characteristics of the first embodiment are close to those in the case where the resistance value R_{L} is 150 ohms (Ω) and are good, although the resistance value R_{L} is 300 ohms (Ω).

In addition, as illustrated in b of the figure, the noise characteristics of the first embodiment are similar to those of the comparative example in the case where the resistance value R_{L} is 300 ohms (Ω), and are good.

As illustrated in the figure, the trade-off between the frequency characteristics and the noise characteristics can be eliminated by the connection of the negative feedback amplifier circuit 450.

### Configuration Example of Negative Feedback Amplifier Circuit

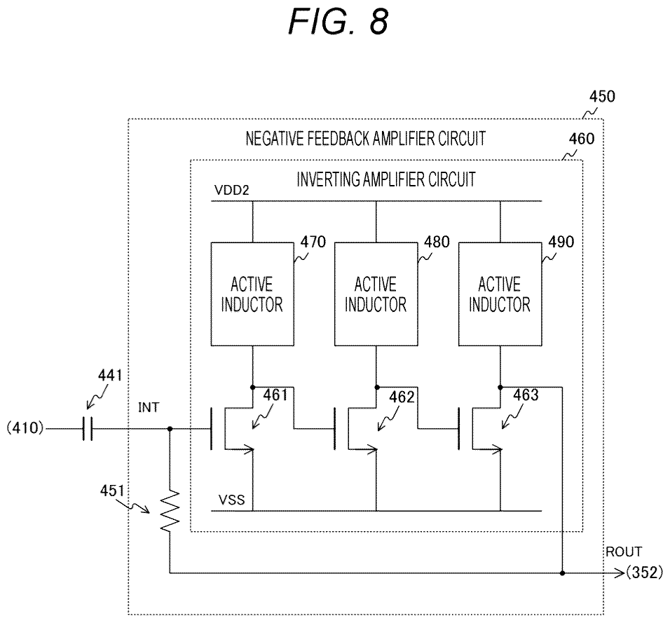

FIG. 8 is a circuit diagram illustrating a configuration example of the negative feedback amplifier circuit 450 in the first embodiment of the present technology. In the negative feedback amplifier circuit 450 of the first embodiment, the inverting amplifier circuit 460 includes inverting amplifier transistors 461 to 463 and active inductors 470, 480, and 490. As the inverting amplifier transistors 461 to 463, nMOS transistors are used, for example.

In addition, a capacitor 441 is inserted between the common-gate amplifier circuit 410 and the negative feedback amplifier circuit 450.

An internal signal INT from the common-gate amplifier circuit 410 is input to the gate of the inverting amplifier transistor 461 of the first stage, and the source thereof is grounded. The gate of the inverting amplifier transistor 462 of the second stage is connected to the drain of the inverting amplifier transistor 461, and the source thereof is grounded. The gate of the inverting amplifier transistor 463 of the third stage is connected to the drain of the inverting amplifier transistor 462, and the source thereof is grounded. An output signal ROUT is output from the drain of the inverting amplifier transistor 463.

With the above-described connection, each of the inverting amplifier transistors 461, 462, and 463 inverts and amplifies a signal from the preceding stage and outputs the signal. Note that the inverting amplifier transistors have three stages, but the number of stages is not limited to three as long as it is an odd number. In a case where the number of stages is increased or decreased, the number of active transistors is also increased or decreased according to the number of stages.

In addition, the active inductor 470 is inserted between the drain of the inverting amplifier transistor 461 and a node of a power supply voltage VDD2. The active inductor 480 is inserted between the drain of the inverting amplifier transistor 462 and the node of the power supply voltage VDD2. The active inductor 490 is inserted between the drain of the inverting amplifier transistor 463 and the node of the power supply voltage VDD2.

In addition, the negative feedback resistor 451 is inserted between the gate of the inverting amplifier transistor 461 (that is, the input terminal of the inverting amplifier circuit 460) and the drain of the inverting amplifier transistor 463 (that is, the output terminal of the inverting amplifier circuit 460).

As illustrated in the figure, the low noise amplifier 400 can be operated in a higher band by using the active inductors 470, 480, and 490. Note that the active inductors 470, 480, and 490 may not be disposed in a case where the necessity for a higher band is low.

### Configuration Example of Active Inductors

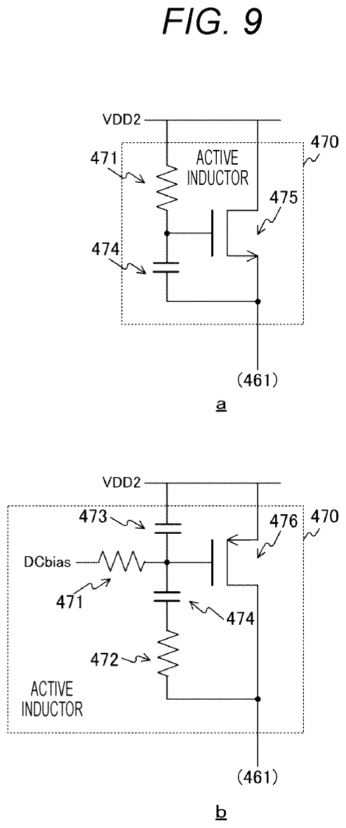

FIG. 9 is a circuit diagram illustrating a configuration example of the active inductor 470 in the first embodiment of the present technology. In the figure, a is a circuit diagram of the active inductor 470 in which a general circuit is used. In the figure, b is a circuit diagram of the improved active inductor 470. Note that the circuit configurations of the active inductors 480 and 490 are similar to that of the active inductor 470.

As illustrated in a of the figure, in a general circuit, a resistor 471, a capacitor 474, and an nMOS transistor 475 are disposed in the active inductor 470. The resistor 471 and the capacitor 474 are inserted in series between the node of the power supply voltage VDD2 and the inverting amplifier transistor 461 with the resistor 471 disposed on the power supply side. The nMOS transistor 475 is inserted between the node of the power supply voltage VDD2 and the inverting amplifier transistor 461, and the gate thereof is connected to a connection node between the resistor 471 and the capacitor 473.

With the circuit configuration illustrated in a of the figure, the nMOS transistor 475 can be brought into a diode-connected state in an alternating current manner at a relatively low frequency, and can be brought into a common-gate state at a high frequency. The frequency response is controlled by the time constant of the RC circuit. As a result, at a low frequency, the load is 1/gm, where gm is the transconductance of the nMOS transistor 475. In contrast, at a high frequency, the load is ro, where ro is the value of the resistor 471. Thus, the frequency characteristics equivalent to those of a coil can be achieved with the transistor.

The circuit in a of the figure has a strict operating point, and it is therefore desirable that the circuit be improved as illustrated in b of the figure. In this case, resistors 471 and 472, capacitors 473 and 474, and a pMOS transistor 476 are disposed in the active inductor 470.

The capacitor 473, the capacitor 474, and the resistor 472 are inserted in series between the node of the power supply voltage VDD2 and the inverting amplifier transistor 461. The pMOS transistor 476 is inserted between the node of the power supply voltage VDD2 and the inverting amplifier transistor 461, and the gate thereof is connected to a connection node between the capacitor 473 and the capacitor 474. In addition, one end of the resistor 471 is connected to DCbias, which is a constant bias voltage, and the other end thereof is connected to the connection node between the capacitor 473 and the capacitor 474.

For example, the value of the resistor 471 is set to 100 kilohms (kΩ), the value of the resistor 472 is set to 100 ohms (Ω), the capacitance of the capacitor 473 is set to 60 femtofarads (fF), and the value of the capacitor 474 is set to 1 picofarad (pF). The voltage of the power supply voltage VDD2 is set to 0.8 volts (V), and DCbias is set to 0.5 volts (V). With this setting, the frequency characteristics around 10 gigahertz (Gz) can be improved. Note that 1 picofarad (pF) of the capacitor 474 is a value for DC cutting, and is only required to be a value sufficiently greater than 60 femtofarads (fF).

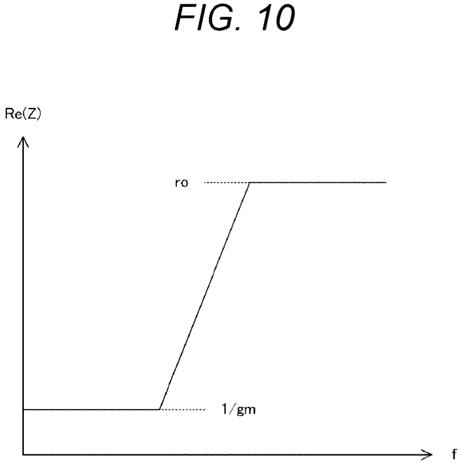

FIG. 10 is a graph illustrating an example of the frequency characteristics of the active inductor 470 in the first embodiment of the present technology. In the figure, the vertical axis represents the impedance, and the horizontal axis represents the frequency. As illustrated in the figure, the impedance is 1/gm at a relatively low frequency, and is ro at a high frequency.

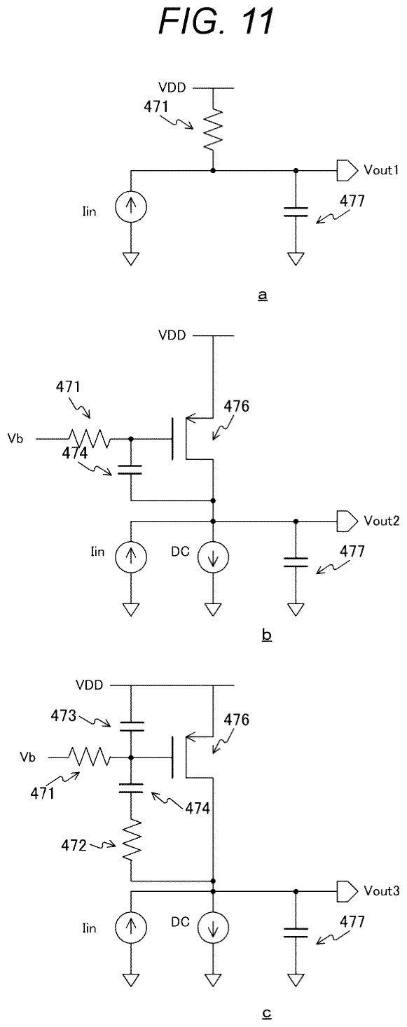

FIG. 11 is a diagram illustrating examples of circuits used in simulations in the first embodiment of the present technology. In the figure, a is an example of a circuit to be compared in which only the resistor 471 is connected to a capacitive load 477. In the figure, b is an example of a circuit in which a general active inductor is connected to the capacitive load 477. In the figure, c is an example of a circuit in which an improved active inductor is connected to the capacitive load 477.

In a of the figure, the value of the resistor 471 was set to 46 ohms (Ω), and the value of the capacitive load 477 was set to 200 farads (F). In addition, the voltage at a connection node between the resistor 471 and the capacitive load 477 was set to Vout1, and the frequency characteristics were obtained by simulation.

In b of the figure, the general active inductor including the resistor 471, the capacitor 474, and the pMOS transistor 476 was connected. The value of the resistor 471 was set to 100 kilohms (kΩ), the value of the capacitor 474 was set to 1 picofarad (pF), and the transconductance gm of the pMOS transistor 476 was set to 1/46. In addition, the voltage of a connection node between the active inductor and the capacitive load 477 was set to Vout2, and the frequency characteristics were obtained by simulation.

In c of the figure, the active inductor including the resistors 471 and 472, the capacitors 473 and 474, and the pMOS transistor 476 was connected. The value of the resistor 472 was set to 100 ohms (Ω) and the value of the capacitor 473 was set to 60 femtofarads (fF). In addition, the voltage of a connection node between the active inductor and the capacitive load 477 was set to Vout3, and the frequency characteristics were obtained by simulation.

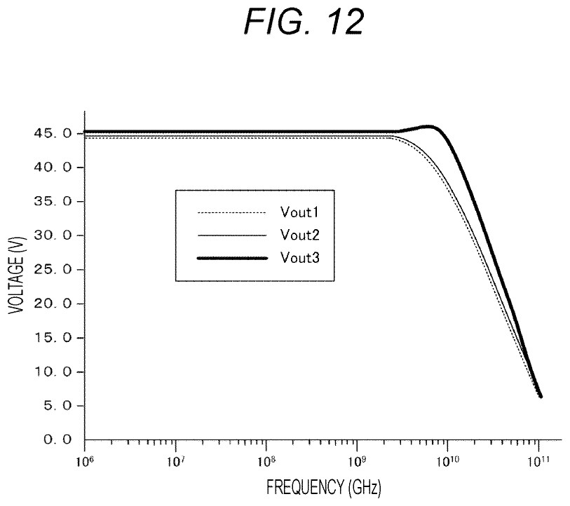

FIG. 12 is a graph illustrating an example of simulation results in the first embodiment of the present technology. In the figure, the vertical axis represents voltages Vout1 to Vout3, and the horizontal axis represents the frequency. In addition, a dotted line indicates the frequency characteristics of Vout1, a thin solid line indicates the frequency characteristics of Vout2, and a thick solid line indicates the frequency characteristics of Vout3.

As illustrated in the figure, adopting the circuit configuration of c of FIG. 11 can improve the frequency characteristics and widen the operating band.

### Configuration Example of Sensor Control Unit

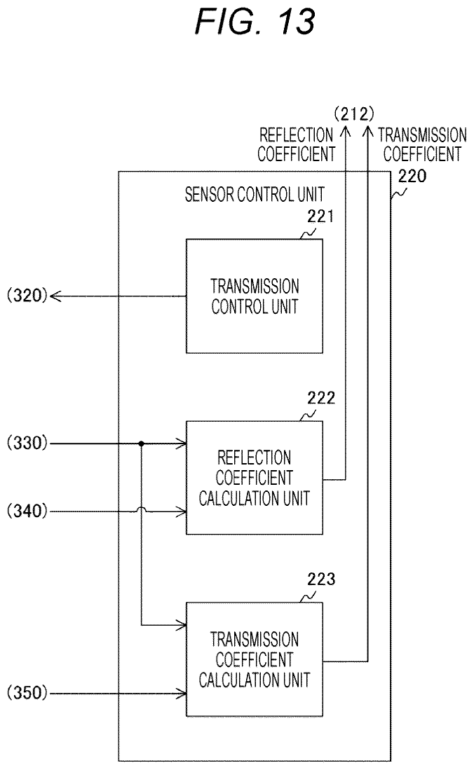

FIG. 13 is a block diagram illustrating a configuration example of the sensor control unit 220 in the first embodiment of the present technology. The sensor control unit 220 includes a transmission control unit 221, a reflection coefficient calculation unit 222, and a transmission coefficient calculation unit 223.

The transmission control unit 221 controls the transmitter 320 to cause the transmitter 320 to transmit a transmission signal.

The reflection coefficient calculation unit 222 calculates a reflection coefficient Γ for each frequency. The reflection coefficient calculation unit 222 receives the respective S parameters of an incident wave and a reflected wave from the incident wave receiver 330 and the reflected wave receiver 340, and calculates the ratio thereof as the reflection coefficient Γ by the following equation.

$$Γ = ( {I}_{R} + {jQ}_{R} ) / ( {I}_{I} + {jQ}_{I} ) \qquad Equation 2$$

In the above equation, j is an imaginary unit. IR and O_{R} are in-phase and quadrature components generated by the reflected wave receiver 340. I_{I} and Q_{I} are in-phase and quadrature components generated by the incident wave receiver 330.

The reflection coefficient calculation unit 222 calculates a reflection coefficient by Equation 2 for each of N (N is an integer) frequencies f₁ to f_{N}. The N reflection coefficients are defined as reflection coefficients Γ₁ to Γ_{N}. The reflection coefficient calculation unit 222 supplies the reflection coefficients to the sensor communication unit 212.

The transmission coefficient calculation unit 223 calculates a transmission coefficient T for each frequency. The transmission coefficient calculation unit 223 receives the respective S parameters of an incident wave and a transmitted wave from the incident wave receiver 330 and the transmitted wave receiver 350, and calculates the ratio thereof as a transmission coefficient T by the following equation.

$$T = ( {I}_{T} + {jQ}_{T} ) / ( {I}_{I} + {jQ}_{I} ) \qquad Equation 3$$

In the above equation, I_{T} and Q_{T} are in-phase and quadrature components generated by the transmitted wave receiver 350.

The transmission coefficient calculation unit 223 calculates a transmission coefficient by Equation 3 for each of the N frequencies f₁ to f_{N}. The N reflection coefficients are defined as reflection coefficients T₁ to T_{N}. The transmission coefficient calculation unit 223 supplies the transmission coefficients to the central processing unit 150 via the sensor communication unit 212.

Note that the reflection coefficient calculation unit 222 and the transmission coefficient calculation unit 223 are examples of the coefficient calculation unit recited in the claims.

### Configuration Example of Central Processing Unit

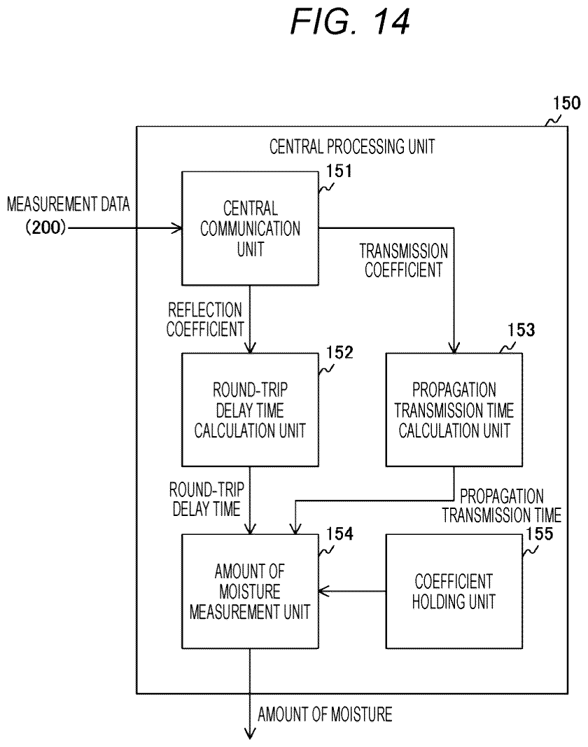

FIG. 14 is a block diagram illustrating a configuration example of the central processing unit 150 in the first embodiment of the present technology. The central processing unit 150 includes a central communication unit 151, a round-trip delay time calculation unit 152, a propagation transmission time calculation unit 153, an amount of moisture measurement unit 154, and a coefficient holding unit 155.

The central communication unit 151 receives measurement data from the sensor device 200 or the like. The central communication unit 151 supplies the reflection coefficients Γ₁ to Γ_{N} in the measurement data to the round-trip delay time calculation unit 152, and supplies the transmission coefficients T₁ to T_{N} in the measurement data to the propagation transmission time calculation unit 153.

The round-trip delay time calculation unit 152 calculates the time taken for a transmission signal (electric signal) to make a round trip through a transmission path in the transmission probe 230, as a round-trip delay time, on the basis of the reflection coefficients. The round-trip delay time calculation unit 152 obtains an impulse response hΓ(t) by performing inverse Fourier transform on the reflection coefficients Γ₁ to Γ_{N}. Then, the round-trip delay time calculation unit 152 obtains a time difference between the timing of the peak value of the impulse response hΓ(t) and the transmission timing of a CW, as a round-trip delay time τ₁₁, and supplies it to the amount of moisture measurement unit 154.

The propagation transmission time calculation unit 153 calculates the time taken for an electromagnetic wave and an electric signal to propagate and transmit through the medium and the transmission path in each of the probes, as a propagation transmission time, on the basis of the transmission coefficients. The propagation transmission time calculation unit 153 obtains an impulse response hT(t) by performing inverse Fourier transform on the transmission coefficients T₁ to T_{N}. Then, the propagation transmission time calculation unit 153 obtains a time difference between the timing of the peak value of the impulse response hT(t) and the transmission timing of a CW, as a propagation transmission time τ₂₁, and supplies it to the amount of moisture measurement unit 154.

The amount of moisture measurement unit 154 measures the amount of moisture on the basis of the round-trip delay time τ₁₁ and the propagation transmission time τ₂₁. The amount of moisture measurement unit 154 first calculates a propagation delay time τ_{d} from the round-trip delay time τ₁₁ and the propagation transmission time τ₂₁. Here, the propagation delay time is the time taken for an electromagnetic wave to propagate through the medium between the transmission probe and the reception probe. The propagation delay time τ_{d} is calculated by the following equation.

$${τ}_{d} = {τ}_{21} - {τ}_{11} \qquad Equation 4$$

In the above equation, the unit of each of the round-trip delay time τ₁₁, the propagation transmission time τ₂₁, and the propagation delay time τ_{d} is, for example, nanoseconds (ns).

Then, the amount of moisture measurement unit 154 reads coefficients a and b indicating the relationship between the amount of moisture and the propagation delay time τ_{d} from the coefficient holding unit 155, and substitutes the propagation delay time τ_{d} calculated by Equation 4 into the following equation to measure the amount x of moisture. Then, the amount of moisture measurement unit 154 outputs the measured amount of moisture to an external device or apparatus as necessary.

$${τ}_{d} = a \cdot x + b \qquad Equation 5$$

In the above equation, the unit of the amount x of moisture is, for example, volume percent (%).

The coefficient holding unit 155 holds the coefficients a and b. As the coefficient holding unit 155, a nonvolatile memory or the like is used.

Note that part or all of the processing of the central processing unit 150 can also be executed on the sensor device 200 side.

As described above, according to the first embodiment of the present technology, the inverting amplifier circuit 460 with the negative feedback resistor 451 is connected to the common-gate amplifier circuit 410. It is therefore possible to improve the frequency characteristics while reducing noise more than in the case of the common-gate amplifier circuit 410 only.

### 2. Second Embodiment

While the low noise amplifier 400 amplifies a single-ended signal in the first embodiment described above, a differential signal can also be amplified instead of the single-ended signal. A low noise amplifier 400 in a second embodiment is different from that in the first embodiment in amplifying a differential signal.

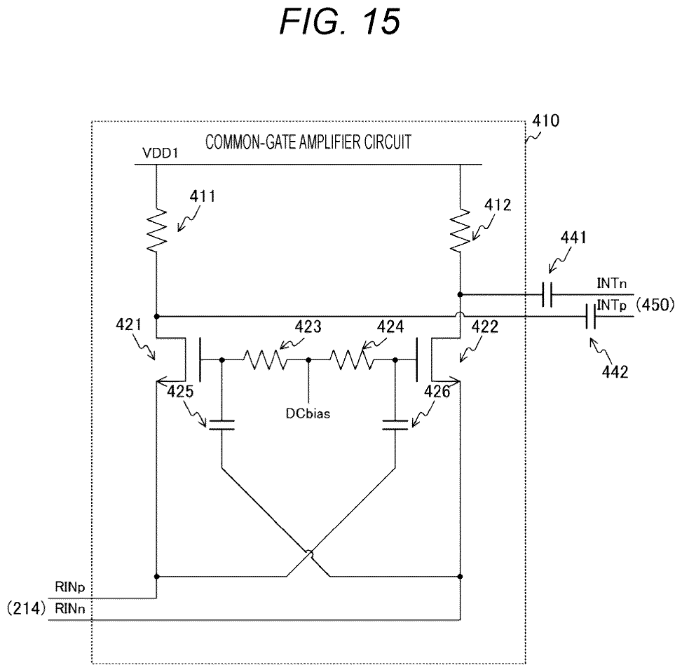

FIG. 15 is a circuit diagram illustrating a configuration example of a common-gate amplifier circuit 410 in the second embodiment of the present technology. The common-gate amplifier circuit 410 of the second embodiment includes load resistors 411 and 412, amplifier transistors 421 and 422, resistors 423 and 424, and capacitors 425 and 426.

In addition, a reception signal input to the common-gate amplifier circuit 410 of the second embodiment is a differential signal including a positive side signal RINp and a negative side signal RINn.

The positive side signal RINp is input to the source of the amplifier transistor 421, and the load resistor 411 is inserted between the drain thereof and a node of a power supply voltage VDD1. The negative side signal RINn is input to the source of the amplifier transistor 422, and the load resistor 412 is inserted between the drain thereof and the node of the power supply voltage VDD1. A positive side signal INTp is output from the drain of the amplifier transistor 421 via a capacitor 442, and a negative side signal INTn is output from the drain of the amplifier transistor 422 via a capacitor 441. A differential signal including the positive side signal INTp and the negative side signal INTn is an internal signal.

Furthermore, the resistors 423 and 424 are connected in series between the respective gates of the amplifier transistors 421 and 422. A connection node between these resistors is connected to DCbias.

The capacitor 425 is inserted between the gate of the amplifier transistor 421 and the source of the amplifier transistor 422. The capacitor 426 is inserted between the gate of the amplifier transistor 422 and the source of the amplifier transistor 421.

The common-gate amplifier circuit 410 having the circuit configuration illustrated in the figure differentially amplifies a reception signal that is a differential signal.

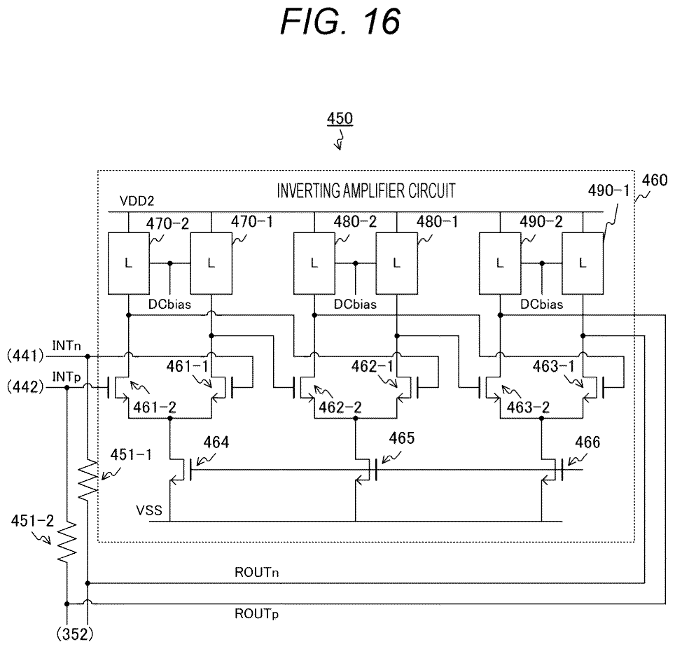

FIG. 16 is a circuit diagram illustrating a configuration example of a negative feedback amplifier circuit 450 in the second embodiment of the present technology. The negative feedback amplifier circuit 450 of the second embodiment includes negative feedback resistors 451-1 and 451-2 and an inverting amplifier circuit 460.

The inverting amplifier circuit 460 of the second embodiment includes active inductors 470-1, 470-2, 480-1, 480-2, 490-1, and 490-2. In addition, the inverting amplifier circuit 460 further includes inverting amplifier transistors 461-1, 461-2, 462-1, 462-2, 463-1, and 463-2 and tail current sources 464 to 466.

The negative side signal INTn and the positive side signal INTp are input to the gates of the inverting amplifier transistors 461-1 and 461-2 of the first stage, and the sources thereof are connected in common to the tail current source 464. The active inductors 470-1 and 470-2 are inserted between a node of a power supply voltage VDD2 and the drains of the inverting amplifier transistors 461-1 and 461-2.

The gates of the inverting amplifier transistors 462-1 and 462-2 of the second stage are connected to the inverting amplifier transistors 461-2 and 461-1, and the sources thereof are connected in common to the tail current source 465. The active inductors 480-1 and 480-2 are inserted between the node of the power supply voltage VDD2 and the drains of the inverting amplifier transistors 462-1 and 462-2.

The gates of the inverting amplifier transistors 463-1 and 463-2 of the third stage are connected to the inverting amplifier transistors 462-2 and 462-1, and the sources thereof are connected in common to the tail current source 466. The active inductors 490-1 and 490-2 are inserted between the node of the power supply voltage VDD2 and the drains of the inverting amplifier transistors 463-1 and 463-2. A negative side signal ROUTn and a positive side signal ROUTp are output from the drains of the inverting amplifier transistors 463-1 and 463-2. A differential signal including the negative side signal ROUTn and the positive side signal ROUTp is an output signal.

Furthermore, the negative feedback resistor 451-1 is inserted between the gate of the inverting amplifier transistor 461-1 and the drain of the inverting amplifier transistor 463-1. The negative feedback resistor 451-2 is inserted between the gate of the inverting amplifier transistor 461-2 and the drain of the inverting amplifier transistor 463-2.

The inverting amplifier circuit 460 having the circuit configuration illustrated in the figure differentially amplifies an internal signal that is a differential signal.

Note that the inverting amplifier transistors on each of the positive side and the negative side have three stages, but the number of stages is not limited to three as long as it is an odd number.

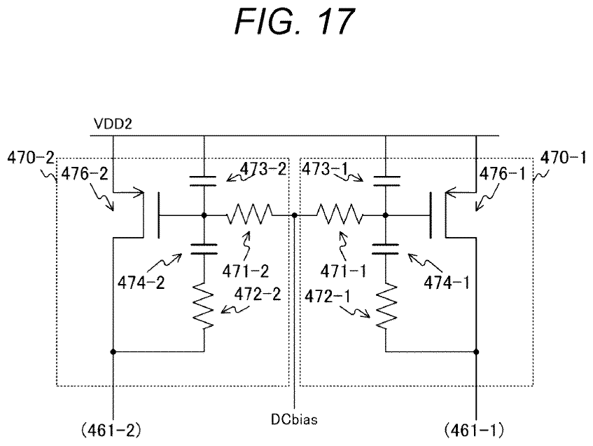

FIG. 17 is a circuit diagram illustrating a configuration example of the active inductors 470-1 and 470-2 in the second embodiment of the present technology. The active inductor 470-1 includes resistors 471-1 and 472-1, capacitors 473-1 and 474-1, and a pMOS transistor 476-1. The active inductor 470-2 includes resistors 471-2 and 472-2, capacitors 473-2 and 474-2, and a pMOS transistor 476-2. The connection configuration of the elements in the active inductor 470-1 is similar to the connection configuration of the elements in the active inductor 470 illustrated in b of FIG. 9. The active inductor 470-2 also has a similar connection configuration.

The low noise amplifier 400 amplifies a differential signal, thereby reduces common mode noise and the like as compared to those in a case where a single-ended signal is amplified, and can further improve the noise characteristics.

As described above, according to the second embodiment of the present technology, the low noise amplifier 400 amplifies a differential signal, and thus can further improve the noise characteristics.

Note that the embodiments described above show examples for embodying the present technology, and the matters in the embodiments and the matters specifying the invention in the claims have corresponding relationships, respectively. Similarly, the matters specifying the invention in the claims and matters with the same names in the embodiments of the present technology have correspondence relationships. However, the present technology is not limited to the embodiments, and can be embodied by applying various modifications to the embodiments without departing from the gist of the present technology.

Note that effects described in the present specification are merely examples and are not limited, and other effects may be provided.

Note that the present technology may also have the following configurations.

(1) A low noise amplifier including:
a common-gate amplifier circuit that amplifies a reception signal and outputs the amplified reception signal as an internal signal;
an inverting amplifier circuit that inverts and amplifies the internal signal and outputs the inverted and amplified internal signal as an output signal; and
a negative feedback resistor inserted between an input terminal and an output terminal of the inverting amplifier circuit.

(2) The low noise amplifier according to (1),
in which the common-gate amplifier circuit includes:
an amplifier transistor that amplifies the reception signal input to a source and outputs the amplified reception signal from a drain; and
a load resistor inserted between the drain of the amplifier transistor and a node of a predetermined voltage.

(3) The low noise amplifier according to (1) or (2),
in which the inverting amplifier circuit includes:
an inverting amplifier transistor that inverts and amplifies the internal signal input to a gate and outputs the inverted and amplified internal signal from a drain; and
an active inductor connected to the drain of the inverting amplifier transistor.

(4) The low noise amplifier according to any one of (1) to (3),
in which the reception signal and the internal signal are single-ended signals.

(5) The low noise amplifier according to any one of (1) to (3),
in which the reception signal and the internal signal are differential signals, and
the common-gate amplifier circuit and the inverting amplifier circuit are circuits that perform differential amplification.

(6) A sensor device including:
a common-gate amplifier circuit that amplifies a reception signal and outputs the amplified reception signal as an internal signal;
an inverting amplifier circuit that inverts and amplifies the internal signal and outputs the inverted and amplified internal signal as an output signal;
a negative feedback resistor inserted between an input terminal and an output terminal of the inverting amplifier circuit; and
a mixer that mixes the output signal and a predetermined local signal.

(7) The sensor device according to (6), further including
a transmitter that outputs a transmission signal,
in which the common-gate amplifier circuit, the inverting amplifier circuit, the negative feedback resistor, and the mixer are disposed in a receiver, and
the transmitter and the receiver are disposed on a predetermined semiconductor chip.

(8) The sensor device according to (7), further including
a directional coupler that separates an incident wave and a reflected wave in the transmission signal,
in which the receiver includes:
an incident wave receiver that receives the incident wave;
a reflected wave receiver that receives the reflected wave; and
a transmitted wave receiver that receives a transmitted wave transmitted through a predetermined medium, and
the common-gate amplifier circuit, the inverting amplifier circuit, the negative feedback resistor, and the mixer are disposed in the transmitted wave receiver.

(9) The sensor device according to (8),
in which a frequency of the local signal is 1 to 9 gigahertz (GHz).

(10) The sensor device according to (8), further including
a coefficient calculation unit that calculates a coefficient for measuring an amount of moisture in the medium on a basis of the output signal.

### REFERENCE SIGNS LIST

100 Moisture measurement system
110 Communication path
150 Central processing unit
151 Central communication unit
152 Round-trip delay time calculation unit
153 Propagation transmission time calculation unit
154 Amount of moisture measurement unit
155 Coefficient holding unit
200, 201 Sensor device
210 Semiconductor chip
211 Antenna
212 Sensor communication unit
213 Transmission switch
214 Reception switch
220 Sensor control unit
221 Transmission control unit
222 Reflection coefficient calculation unit
223 Transmission coefficient calculation unit
230 Transmission probe
231 to 233 Transmission antenna
240 Reception probe
241 to 243 Reception antenna
300 Vector network analyzer
310 Directional coupler
320 Transmitter
321 Power amplifier
322 Local oscillator
330 Incident wave receiver
331, 341, 400 Low noise amplifier
332, 342, 352 Mixer
333, 343, 353 Band-pass filter
334, 344, 354 ADC
340 Reflected wave receiver
350 Transmitted wave receiver
410 Common-gate amplifier circuit
411, 412 Load resistor
421, 422 Amplifier transistor
423, 424, 471, 471-1, 471-2, 472, 472-1, 472-2 Resistor
425, 426, 441, 442, 473, 473-1, 473-2, 474, 474-1, 474-2 Capacitor
450 Negative feedback amplifier circuit
451, 451-1, 451-2 Negative feedback resistor
460 Inverting amplifier circuit
461, 461-1, 461-2, 462, 462-1, 462-2, 463, 463-1, 463-2 Inverting amplifier transistor
464, 465, 466 Tail current source
470, 470-1, 470-2, 480, 480-1, 480-2, 490, 490-1, 490-2 Active inductor
475 nMOS transistor
476, 476-1, 476-2 pMOS transistor
477 Capacitive load

1. A low noise amplifier comprising:
a common-gate amplifier circuit that amplifies a reception signal and outputs the amplified reception signal as an internal signal;
an inverting amplifier circuit that inverts and amplifies the internal signal and outputs the inverted and amplified internal signal as an output signal; and
a negative feedback resistor inserted between an input terminal and an output terminal of the inverting amplifier circuit.

2. The low noise amplifier according to claim 1,
wherein the common-gate amplifier circuit includes:
an amplifier transistor that amplifies the reception signal input to a source and outputs the amplified reception signal from a drain; and
a load resistor inserted between the drain of the amplifier transistor and a node of a predetermined voltage.

3. The low noise amplifier according to claim 1,
wherein the inverting amplifier circuit includes:
an inverting amplifier transistor that inverts and amplifies the internal signal input to a gate and outputs the inverted and amplified internal signal from a drain; and
an active inductor connected to the drain of the inverting amplifier transistor.

4. The low noise amplifier according to claim 1,
wherein the reception signal and the internal signal are single-ended signals.

5. The low noise amplifier according to claim 1,
wherein the reception signal and the internal signal are differential signals, and
the common-gate amplifier circuit and the inverting amplifier circuit are circuits that perform differential amplification.

6. A sensor device comprising:
a common-gate amplifier circuit that amplifies a reception signal and outputs the amplified reception signal as an internal signal;
an inverting amplifier circuit that inverts and amplifies the internal signal and outputs the inverted and amplified internal signal as an output signal;
a negative feedback resistor inserted between an input terminal and an output terminal of the inverting amplifier circuit; and
a mixer that mixes the output signal and a predetermined local signal.

7. The sensor device according to claim 6, further comprising
a transmitter that outputs a transmission signal,
wherein the common-gate amplifier circuit, the inverting amplifier circuit, the negative feedback resistor, and the mixer are disposed in a receiver, and
the transmitter and the receiver are disposed on a predetermined semiconductor chip.

8. The sensor device according to claim 7, further comprising
a directional coupler that separates an incident wave and a reflected wave in the transmission signal,
wherein the receiver includes:
an incident wave receiver that receives the incident wave;
a reflected wave receiver that receives the reflected wave; and
a transmitted wave receiver that receives a transmitted wave transmitted through a predetermined medium, and
the common-gate amplifier circuit, the inverting amplifier circuit, the negative feedback resistor, and the mixer are disposed in the transmitted wave receiver.

9. The sensor device according to claim 8,
wherein a frequency of the local signal is 1 to 9 gigahertz (GHz).

10. The sensor device according to claim 8, further comprising
a coefficient calculation unit that calculates a coefficient for measuring an amount of moisture in the medium on a basis of the output signal.
